(19) United States
(12) Patent Application Publication
(10) Pub. No.: US 2009/0190319 A1
(43) Pub. Date: Jul. 30, 2009

(54) THREE-DIMENSIONAL MODULE

(75) Inventor: Tomoyuki HATAKEYAMA, Hachioji-shi (JP)

Correspondence Address: SCULLY SCOTT MURPHY & PRESSER, PC, 400 GARDEN CITY PLAZA, SUITE 300, GARDEN CITY, NY, 11530, US

(73) Assignee: OLYMPUS CORPORATION, Tokyo (JP)

(21) Appl. No.: 12/357,809

(22) Filed: Jan. 22, 2009

(30) Foreign Application Priority Data
Jan. 24, 2008 (JP) 2008-014000

(51) Int. Cl. H05K 1/14

(52) U.S. Cl. 361/803

(57) ABSTRACT

A three-dimensional module having a first substrate holding a function element, and a second substrate holding other components. The first and second substrates are laid one above the other in a three-dimensional fashion, and are electrically and mechanically connected. The module has inter-substrate joining members interposed between the first and second substrates and joining the first and second substrates. Each inter-substrate joining member has a stress-absorption member and an electrically conductive stress-absorption member. The stress-absorption member has elasticity and mechanically joining the first and second substrates. The electrically conductive stress-absorption member connects the first and second substrates and can deform in a desirable direction.

### CROSS-REFERENCE TO RELATED APPLICATIONS

This application is based upon and claims the benefit of priority from prior Japanese Patent Application No. 2008-014000, filed Jan. 24, 2008, the entire contents of which are incorporated herein by reference.

### BACKGROUND OF THE INVENTION

1. Field of the Invention

The present invention relates to a three-dimensional module having a function element such as a MEMS.

2. Description of the Related Art

Multi-chip modules incorporating a micro-electromechanical system (MEMS) are disclosed in, for example, Jpn. Pat. Appln. KOKAI Publication No. 2006-173458. The multi-chip module disclosed in Jpn. Pat. Appln. KOKAI Publication No. 2006-173458 will be briefly described, with reference to FIG. 11. As FIG. 11 shows, first to fourth substrates 131 to 134, each having a chip-shaped device mounted on the upper surface, are stacked one on another. (The chip-shaped device comprises a laminated DRAM section A, a fine passive element section B, a DSP section C, and a sensor MEMS section D.) Each substrate has through-interconnects 135 provided in through holes, each made in the substrate and opening at the upper and lower side of the substrate. The substrates 131, 132 and 133 have holes or a holes each hole 136 exposing that part of the immediately lower substrate, on which a device is mounted.

This multi-chip module is so designed that the devices may be easily connected by simple interconnects and may not influence one another.

### BRIEF SUMMARY OF THE INVENTION

This invention has been made in view of the foregoing. An object of the invention is to provide a small three-dimensional module that can suppress the influence imposed on a function element such as MEMS.

To achieve this object, a three-dimensional module according to this invention has a first substrate holding a function element, a second substrate holding other components, laid on the first substrate in a three-dimensional fashion and jointed to the first substrate electrically and mechanically. The module comprises an inter-substrate joining member interposed between the first substrate and the second substrate, joining the first substrate and the second substrate. The inter-substrate joining member comprises a stress-absorption member having elasticity and mechanically joining the first substrate and the second substrate; and electrically conductive stress-absorption members mechanically joining the first substrate and the second substrate.

Advantages of the invention will be set forth in the description which follows, and in part will be obvious from the description, or may be learned by practice of the invention. Advantages of the invention may be realized and obtained by means of the instrumentalities and combinations particularly pointed out hereinafter.

### BRIEF DESCRIPTION OF THE SEVERAL VIEWS OF THE DRAWING

The accompanying drawings, which are incorporated in and constitute a part of the specification, illustrate embodiments of the invention, and together with the general description given above and the detailed description of the embodiments given below, serve to explain the principles of the invention.

FIG. 1 is a perspective view of a microchip according to a first embodiment of this invention;

FIG. 2 is an exploded perspective view of a three-dimensional module according to the first embodiment of the invention;

FIG. 3 is a sectional view of the three-dimensional module shown in FIG. 2, taken along line A-A in FIG. 2;

FIG. 4 is a sectional view of the three-dimensional module according to the first embodiment, illustrating how the substrate of the module may warp;

FIG. 5 is an exploded perspective view of a three-dimensional module according to a second embodiment of this invention;

FIG. 6 is a sectional view of the three-dimensional module shown in FIG. 5, taken along line B-B in FIG. 5;

FIG. 7 is a sectional view of the three-dimensional module according to the second embodiment, illustrating how the substrate of the module may warp;

FIG. 8 is an exploded perspective view of a three-dimensional module according to a variation of the second embodiment of this invention;

FIG. 9 is a diagram showing the positional relationship that the stress absorption unit, conductivity fixation unit and stress absorption unit have in the second embodiment;

FIG. 10 is a sectional view of the three-dimensional module of FIG. 8, taken along line C-C in FIG. 8; and

FIG. 11 is a sectional view of a conventional multi-chip module.

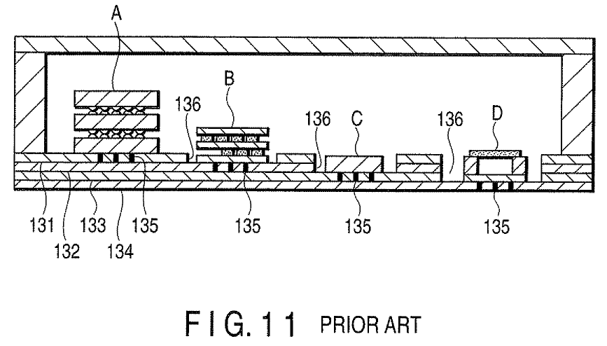

### DETAILED DESCRIPTION OF THE INVENTION

Embodiments of the present invention will be described in detail, with reference to the accompanying drawings.

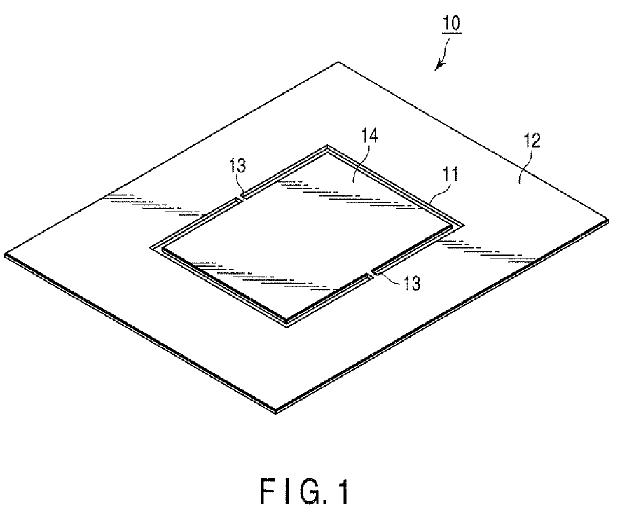

A first embodiment of the invention will be described with reference to FIGS. 1 to 4.

As shown in FIG. 1, a micromirror chip 10 has a mirror supporting part 12, a movable mirror part 14, and hinge parts 13. The mirror supporting part 12 has an opening 11 made in the center part. The movable mirror part 14 is a function element. The movable mirror part 14 is arranged in the opening 11 and supported by the mirror supporting part 12. The hinge parts 13 is support main part. The hinge parts 13 constitute a support unit and mechanically and continuously connect the mirror supporting part 12 and the movable mirror part 14.

The mirror support part 12 is a substantially flat member and is rectangular. The mirror supporting part 12 is a mirror support member that cooperates with the hinge parts 13, supporting the movable mirror part 14 in the opening 11. The opening 11 has a shape similar to that of the mirror supporting part 12, preferably being rectangular. The movable mirror part 14 can move (or incline) around the hinge parts 3 by an electrostatic attraction, which will be described later.

The mirror supporting part 12, movable mirror part 14 and hinge parts 13 have a small thickness of, for example, about 10 μm to about 20 μm. The reason is that the movable mirror part 14 needs to rotate around the hinge parts 13.

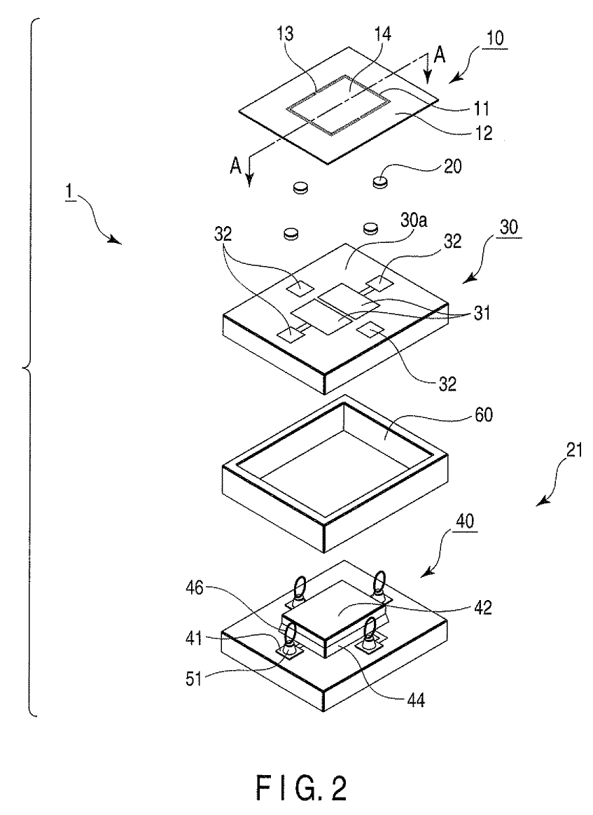

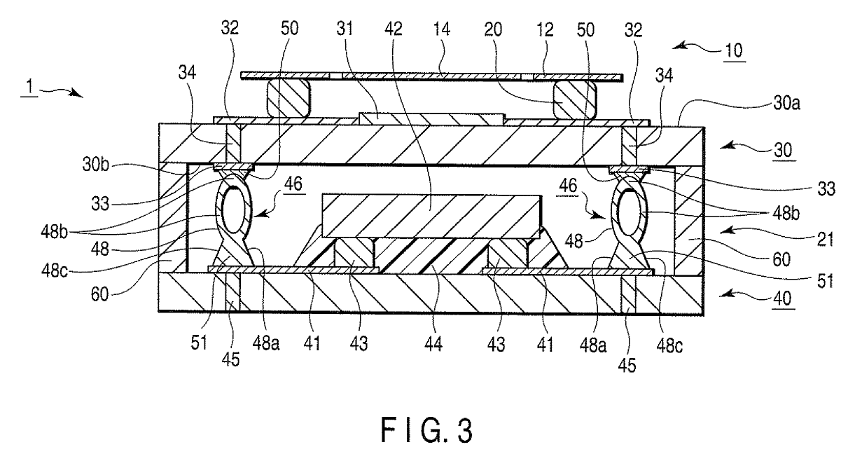

As shown in FIG. 2 and FIG. 3, the micromirror chip 10 is joined by joining members 20 to an electrode substrate 30, and is thereby stacked on the electrode substrate 30 in the direction of thickness. The micromirror chip 10 and the electrode substrate 30 constitute a first substrate for supporting the function element. As shown in FIG. 3, the mirror supporting part 12 and the electrode substrate 30 are appropriately spaced apart by joining members 20. The joining members 20 are made of electrically conductive material such as solder or Au.

As FIG. 2 shows, the micromirror chip 10 (FIG. 1), the electrode substrate 30, and a drive substrate 40 (i.e., a second substrate) are stacked in the direction of thickness, in the three-dimensional module 1. The micromirror chip 10, electrode substrate 30 and drive substrate 40 are connected electrically and mechanically. That surface of the micromirror chip 10, which opposes the electrode substrate 30, is flat. Both surfaces of the electrode substrate 30, which oppose the micromirror chip 10 and the drive substrate 40, respectively, are flat. That surface of the drive substrate 40, which opposes the electrode substrate 30, is flat.

As FIG. 2 shows, drive electrodes 31 and joining electrodes 32 are arranged on the surface 30a of the electrode substrate 30. As FIG. 3 shows, the back joining electrodes 33 are arranged on the back 30b of the electrode substrate 30. Through-electrodes 34 penetrate the electrode substrate 30, each extending in the direction of thickness of the electrode substrate 30. The drive electrodes 31 oppose the movable mirror part 14 and apply an electrostatic attraction to the movable mirror part 14. The joining electrodes 32 are electrically and mechanically connected to the joining members 20 and are electrically connected by the through-electrodes 34 to the back joining electrodes 33

The joining members 20 are joined to the mirror supporting part 12 and the joining electrodes 32. The micromirror chip 10 is thereby laid on, and joined to the electrode substrate 30.

Between the electrode substrate 30 and the drive substrate 40, an inter-substrate joining member 21 is interposed, joining the electrode substrate 30 to the drive substrate 40. The inter-substrate joining member 21 has electrically conductive stress-absorption members 46 and a stress-absorption joining member 60.

As shown in FIG. 2 and FIG. 3, joining electrodes 41 are arranged on the drive substrate 40, each opposing the associated back joining electrode 33. On the joining electrodes 41, components other than the function element, such as an IC 42 that is the control unit of the three-dimensional module 1, are mounted by using bumps 43. The IC 42 is reinforced, encapsulated in a sealing member 44 made of, for example, resin. The joining electrodes 41 are joined to through-electrodes 45 that penetrate the drive substrate 40 in the direction of thickness thereof.

The electrically conductive stress-absorption members 46 are electrically conductive, each arranged between the joining electrode 41 and the back joining electrode 33. The electrically conductive stress-absorption members 46 electrically joining (connect) the electrode substrate 30 and the drive substrate 40, and can deform in such a direction as to absorb the stress that may be generated in, for example, the drive substrate 40 as the substrate 40 warps or bend because of heat or external forces.

Each electrically conductive stress-absorption member 46 has a stress-absorption part 48 and an electrically conductive fixing member 50.

The stress-absorption part 48 is shaped like a ring, and comprises a distal end 48a, a middle part 48b, and a proximal end 48c. The distal end 48a is metal-joined to the joining electrode 41 by means of ultrasonic vibration. A desirable part as a part of the stress-absorption member 48 (e.g., middle part 48b) is bent (curved), thereby metal-joining the proximal end 48c to the proximal end 48c to a desirable part (e.g., distal end 48a). The stress-absorption part 48 is thus shaped like a ring as a whole. The stress-absorption part 48 is an interconnect member such as, for example, an Au interconnect.

More specifically, the distal end 48a is metal-joined to the joining electrode 41, whereby a projection 51 is formed as a part of the distal end 48a. The proximal end 48c is metal-joined to the projection 51. The middle part 48b is bent in the plane of the three-dimensional module 1. When the substrate 40 receives stress, the stress-absorption part 48, which is so shaped as described above, has its middle part 48b bent in a desirable direction and therefore absorbs the stress. Note that the projection 51 is a part (i.e., stress-absorption part 48) of the electrically conductive stress-absorption member 46. The proximal end 48c may be metal-joined to an appropriate part of the stress-absorption part 48, if each stress-absorption part 48 is shaped like a ring, and the middle part 48b of each stress-absorption part 48 can be bent.

The electrically conductive stress-absorption members 46 are arranged, each for one joining electrode 41. It is desired that the electrically conductive stress-absorption members 46 should be arranged around the IC 42, each close to one side of the IC 42.

The electrically conductive fixing members 50 electrically connect the distal ends (e.g., middle parts 48b) of the substrate 40 provided near the electrode substrate 30 to the back joining electrodes 33. As a result, the electrode substrate 30 and the drive substrate 40 are electrically connected to each other. The fixing members 50 are made of electrically conductive adhesive or the like. The electrically conductive fixing members 50 connect the distal ends of the stress-absorption parts 48, which are located on the electrode substrate 30, and the back joining electrodes 33. Instead, they may connect the other appropriate parts of the stress-absorption parts 48 and the back joining electrodes 33, if the middle part 48b of each stress-absorption part 48 can be bent.

The stress-absorption joining member 60 is arranged, surrounding the sides of the drive substrate 40. The stress-absorption joining member 60 is made of, for example, polyimide and is therefore elastic. The stress-absorption joining member 60 is mechanically joined to the back 30b of the electrode substrate 30, mechanically connecting the electrode substrate 30 to the drive substrate 40. When the drive substrate 40 warps and therefore has stress, due to heat or external forces, the stress-absorption joining member 60 deforms in an appropriate direction, absorbing the stress from the drive substrate 40.

The stress-absorption joining member 60 is an elastic member shaped like a rectangular frame as illustrated in FIG. 2. As FIG. 3 shows, the stress-absorption joining member 60 surrounds the back joining electrodes 33, joining electrodes 41, IC 42, electrically conductive stress-absorption members 46 and projections 51. The stress-absorption joining member 60 may have almost the same size as the electrode substrate 30 and drive substrate 40 or may be smaller than the electrode substrate 30 and drive substrate 40, it it only surrounds, as described above, the back joining electrodes 33, joining electrodes 41, IC 42, electrically conductive stress-absorption members 46 and projections 51. Further, the stress-absorption joining member 60 may be arranged close to, and around, the IC 42. The stress-absorption joining member 60 has almost the same height as the electrically conductive stress-absorption members 46.

The stress-absorption joining member 60 is mounted on the same substrate (i.e., drive substrate 40 shown in FIG. 1) as the electrically conductive stress-absorption members 46 are mounted.

Note that the movable mirror part 14 can be mounted on the mirror supporting part 12. Other movable mirror parts may be used. In this case the movable mirror parts, including the movable mirror part 14, may be arranged in a row (in a straight line). Alternatively the movable mirror parts may be arranged in a plurality of rows. Further, the movable mirror part 14 may incline at right angles to the direction it extends in FIG. 1. Moreover, two movable mirror parts 14 may be used, one inclining in the specific direction shown in FIG. 1 and the other inclining at right angles to the specific direction. Thus, the direction in which the movable mirror part 14 inclines is not limited to a particular one.

As shown in FIG. 2, the micromirror chip 10 is joined to the electrode substrate 30 by four joining members 20. The joining members 20 are arranged around the movable mirror part 14. The joining electrodes 32, through-electrodes 34, back joining electrodes 33, electrically conductive fixing members 50 and electrically conductive stress-absorption members 46 are arranged in alignment with the respective joining members 20. Nonetheless, the joining members 20, joining electrodes 32, through-electrodes 34, back joining electrodes 33, fixing members 50 and electrically conductive stress-absorption members 46 are not limited in terms of number or position, if they can join the micromirror chip 10 to the electrode substrate 30 and the electrode substrate 30 and drive substrate 40 to each other and enable the members 46 and stress-absorption joining member 60 to absorb the stress generated in, for example, the drive substrate 40.

Four electrically conductive stress-absorption members 46 are arranged around the IC 42. Nevertheless, the electrically conductive stress-absorption members 46 are not limited in terms of number or position if they electrically connect the electrode substrate 30 and drive substrate 40 and if absorb the stress generated in the drive substrate 40.

How this embodiment operates will be explained.

The joining members 20 join the micromirror chip 10 lying above the electrode substrate 30, to the electrode substrate 30.

The bumps 43 hold the IC 42 on the joining electrodes 41. The sealing member 44 encapsulates the IC 42, reinforcing the IC 42.

The distal ends 48a are metal-joined to the joining electrodes 41 by means of ultrasonic vibration, providing projections 51, each protruding from one joining electrode 41. While the middle part 48b remains bent in the plane of the three-dimensional module 1, the proximal end 48c are metal-joined to the projections 51 by means of ultrasonic vibration. The electrically conductive stress-absorption members 46 shaped like a ring as shown in FIG. 3 are thereby formed. Thus, one electrically conductive stress-absorption member 46 is provided for each joining electrode 41.

The stress-absorption joining member 60 is provided around the drive substrate 40, surrounding the back joining electrodes 33, joining electrodes 41, IC 42, electrically conductive stress-absorption members 46 and projections 51. The stress-absorption joining member 60 is metal-joined to the back 30b of the electrode substrate 30. The fixing members 50 join the middle part 48b to the back joining electrodes 33. The electrode substrate 30 and drive substrate 40 are thereby electrically and mechanically connected to each other. The micromirror chip 10, drive substrate 40 and electrode substrate 30 are thereby joined together, one lying on another. Such a three-dimensional module 1 as shown in FIG. 3 is provided.

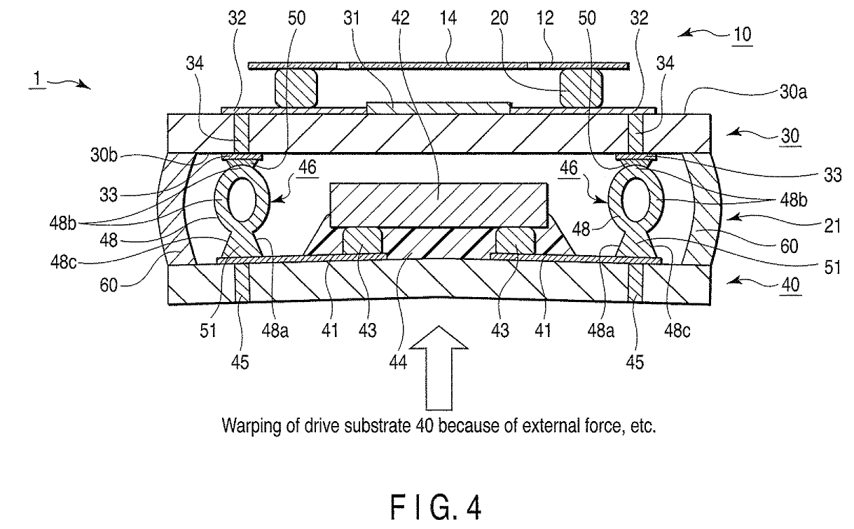

While the three-dimensional module 1 is being produced, or after the module 1 has been incorporated into an apparatus, the drive substrate 40 may warp as shown in FIG. 4 because of external forces or the like. In this case, stress develops in the drive substrate 40 as in most cases. The stress deforms the electrically conductive stress-absorption members 46 and stress-absorption joining member 60 in a desirable direction, in proportion to the warp. In other words, the electrically conductive stress-absorption members 46 and stress-absorption joining member 60 absorb the stress, preventing the stress from being transmitted to the electrode substrate 30 (or suppressing the transmission of the stress).

Hence, the joining members 20 keep the movable mirror part 14 spaced from the drive electrodes 31 by an appropriate distance. The micromirror chip 10 is therefore appropriately spaced from the electrode substrate 30. The three-dimensional module 1 therefore preserves its desirable ability (e.g., optical ability) and its desirable shape. The distance between the micromirror chip 10 and the electrode substrate 30 can be adjusted by changing the thickness of the joining members 20. This helps the three-dimensional module 1 to preserve the desirable ability and shape.

As described above, the electrically conductive stress-absorption members 46 and stress-absorption joining member 60 are arranged on the same substrate (i.e., drive substrate 40 shown in FIG. 1), around and near the IC 42, and can deform in such a direction as to absorb the stress generated in the drive substrate 40. In addition, the stress-absorption members 46 and stress-absorption joining member 60 join the electrode substrate 30 to the drive substrate 40 in the present embodiment. Further, in this embodiment, one joining electrode 41 is provided for each stress-absorption member 46, and neither notches nor holes are provided between the joining electrodes 41 (stress-absorption members 46) or between each stress-absorption member 46 and the stress-absorption joining member 60.

Therefore, the drive substrate 40 can be small in its planer direction. Thus, the three-dimensional module 1 according to this embodiment can be small, requiring but a small mounting area.

Moreover, the drive substrate 40 can be small because the electrically conductive stress-absorption members 46 are arranged close to the IC 42. This serves to reduce the size of the drive substrate 40 and ultimately to reduce the size of the three-dimensional module 1.

In the present embodiment, when stress develops in the drive substrate 40, warping the drive substrate 40, the electrically conductive stress-absorption members 46 and the stress-absorption joining member 60 deform, absorbing the stress. Therefore, the stress is not transmitted to the electrode substrate 30. This keeps the micromirror chip 10 appropriately spaced from the electrode substrate 30, suppressing the influence that the stress imposes on the movable mirror part 14. The three-dimensional module 1 can therefore preserve its desirable ability and its desirable shape.

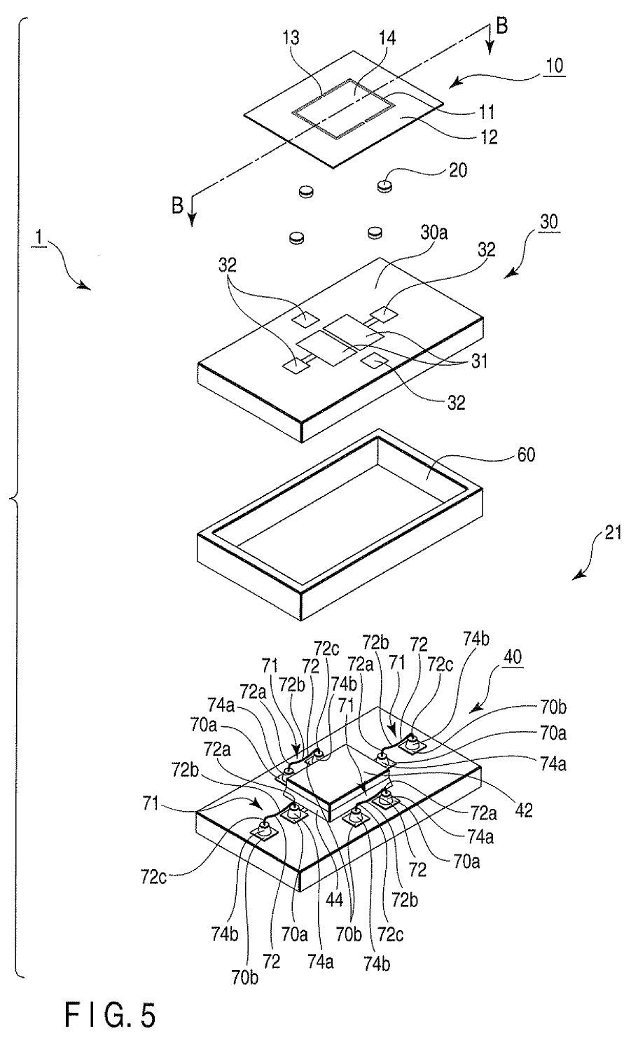

A second embodiment of this invention will be described with reference to FIGS. 5 to 7. The components identical to those of the first embodiment are designated by the same reference numbers and will not be described in detail.

As shown in FIG. 5, four sets of joining electrodes, each set consisting of two joining electrodes 70a and 70b, are arranged around the IC 42. The joining electrodes 70a and 70b of each set are arranged in a line extending below one projection 33a, which will be described later.

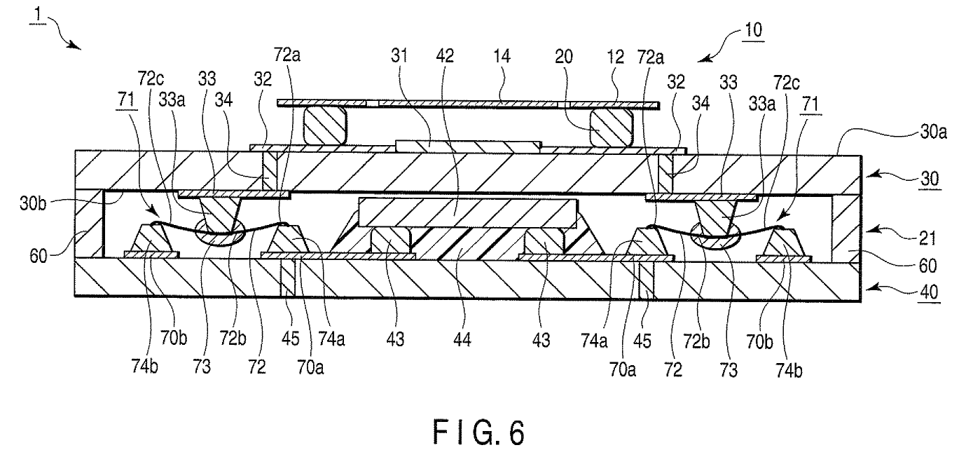

As shown in FIG. 6, bumps 43 connect an IC 42, i.e., main control unit of the three-dimensional module 1, to the joining electrode 70a of each set, as in the first embodiment. The joining electrode 70a of each set is also joined to the associated through-electrode 45 that penetrates the drive substrate 40 in the direction of thickness thereof.

The present embodiment has electrically conductive stress-absorption members 71 that are similar to the electrically conductive stress-absorption members 46 of the first embodiment. Each electrically conductive stress-absorption member 71 is arranged between the jointing electrodes 70a, 70b and the associated back joining electrode 33. The electrically conductive stress-absorption members 71 electrically connect the electrode substrate 30 to the drive substrate 40. The members 71 can deform in a desirable direction when the drive substrate 40, for example, warps or strained. The members 71 can therefore absorb the stress generated in the drive substrate 40 because of the warping or strain. Further, electrically conductive stress-absorption members 71 connect the jointing electrodes 70a and 70b to the projections 33a.

Each electrically conductive stress-absorption member 71 has a stress-absorption member 72, the projections 33a and an electrically conductive fixing part 73.

The stress-absorption member 72 metal-joins the distal end 72a of the member 71 to, for example, the jointing electrode 70a by means of ultrasonic vibration. A desirable part as a part of the stress-absorption member 72 (e.g., middle part 72b) is curved. The proximal end 72c of the stress-absorption member 72 is metal-joined to, for example, the jointing electrode 70b by means of ultrasonic vibration. The stress-absorption member 72 is an interconnect member such as an Au interconnect.

To be more specific, the distal end 72a is metal-joined to the jointing electrode 70a by means of ultrasonic vibration, providing (forming) a projection 74a. The jointing electrode 70b has a projection 74b. The proximal end 72c is metal-joined to the projection 74b by means of ultrasonic vibration. The middle part 72b is curved in the direction of thickness of the three-dimensional module 1, providing a curved part. The middle part 72b does not contact the drive substrate 40, having its height adjusted by the projections 74a and 74b. Since the middle part 72b is curved, the stress-absorption member 72 can deform in a desirable direction. When stress develops in the drive substrate 40, the middle part 72b is bent, deforming in the desired direction. The stress-absorption member 72 therefore absorbs the stress. Further, the stress-absorption member 72 lies at a level lower than the electrically conductive stress-absorption members 46 of the first embodiment since the middle part 72b is curved. Note that the projections 74a and 74b are parts of the electrically conductive stress-absorption member 71 (i.e., stress-absorption member 72).

As shown in FIG. 6, the projections 33a are made of metal such as Au or solder. The projections 33a are members that are arranged on the back joining electrodes 33, respectively, and oppose the middle parts 72b of the stress-absorption members 72, respectively.

The electrically conductive fixing part 73 electrically connects the projection 33a and the middle part 72b. The electrically conductive fixing part 73 is made of electrically conductive adhesive or the like. The electrically conductive fixing part 73 is not limited to one that electrically connects the projection 33a and the middle part 72b. Rather, it may electrically connect a desirable part of the stress-absorption members 72 to the projection 33a if the middle part 72b is curved.

A stress-absorption joining member 60 is arranged, surrounding the sides of the drive substrate 40. The stress-absorption joining member 60 is made of, for example, polyimide and is therefore elastic. The stress-absorption joining member 60 is mechanically joined to the back 30b of the electrode substrate 30, mechanically connecting the electrode substrate 30 to the drive substrate 40. When the electrode substrate 30 and the drive substrate 40 warps and therefore has stress, the stress-absorption joining member 60 deforms in an appropriate direction, absorbing the stress from the electrode substrate 30 and the drive substrate 40. The stress-absorption joining member 60 is shaped like a rectangular frame, surrounding the back joining electrodes 33, IC 42, joining electrodes 70a and 70b, electrically conductive stress-absorption members 71 and projections 33a, 74a and 74b. If the stress-absorption joining member 60 surrounds these components, it can be smaller than the electrode substrate 30, and drive substrate 40 can be arranged close to the IC 42. The stress-absorption joining member 60 has almost the same height as the electrically conductive stress-absorption members 71. The height of the stress-absorption joining member 60 is limited to the height of any component mounted on the drive substrate 40.

The stress-absorption joining member 60 is mounted on the same substrate (i.e., drive substrate 40 shown in FIG. 5) as the electrically conductive stress-absorption members 71 are.

How this embodiment operates will be explained.

The joining members 20 join the micromirror chip 10 to the electrode substrate 30, the chip 10 lying above the electrode substrate 30, as in the first embodiment.

The bumps 43 hold the IC 42 on the joining electrodes 41. The sealing member 44 encapsulates the IC 42, reinforcing the IC 42.

The distal ends 72a are metal-joined to the joining electrodes 70a by means of ultrasonic vibration, providing projections 74a. Next, the proximal ends 72c are metal-joined to the projection 74b by means of ultrasonic vibration, while the middle parts 72b remain curved in the direction of thickness of the third-dimensional module 1.

The stress-absorption joining member 60 arranged around the sides of the drive substrate 40, surrounding the back joining electrodes 33, IC 42, joining electrodes 70a and 70b, electrically conductive stress-absorption members 71 and projections 33a, 74a and 74b. The stress-absorption joining member 60 is joined to the back 30b of the electrode substrate 30. At this point, the electrically conductive fixing part 73 join the middle parts 72b to the projections 33a. The electrode substrate 30 and drive substrate 40 are thereby joined, both electrically and mechanically. The micromirror chip 10, drive substrate 40 and electrode substrate 30 are thereby joined together, one lying on another. Such a three-dimensional module 1 as shown in FIG. 6 is provided.

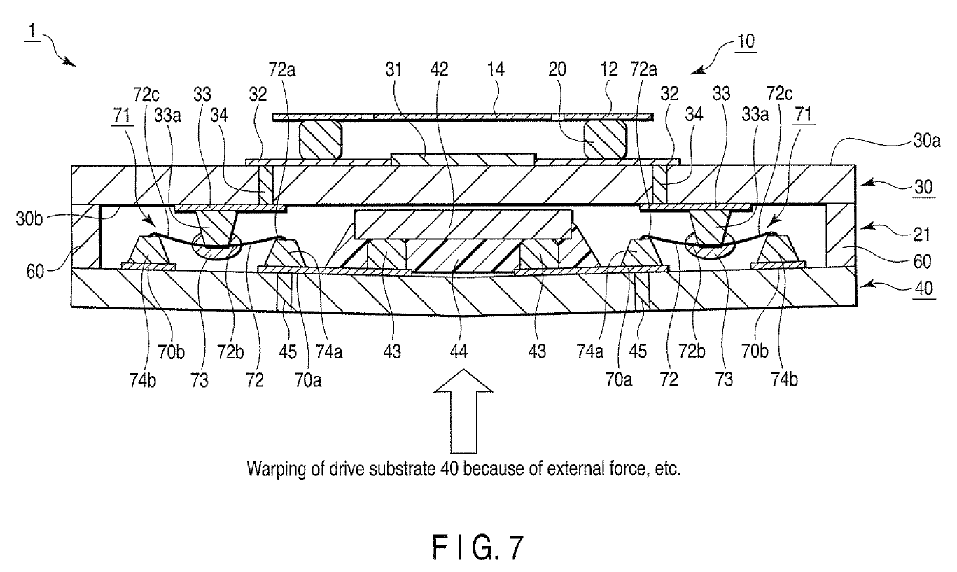

While the three-dimensional module 1 is being produced, or after the module 1 has been incorporated into an apparatus, the drive substrate 40 may warp as shown in FIG. 7 because of external forces or the like. In this case, stress develops in the drive substrate 40 as in most cases. The stress deforms the electrically conductive stress-absorption members 71 and stress-absorption joining member 60 in a desirable direction, in proportion to the warp. Thus, the electrically conductive stress-absorption members 71 and stress-absorption joining member 60 absorb the stress, preventing the stress from being transmitted to the electrode substrate 30.

Therefore, as in the first embodiment, the joining members 20 keep the movable mirror part 14 spaced from the drive electrodes 31 by an appropriate distance. The micromirror chip 10 is thus appropriately spaced from the electrode substrate 30. The three-dimensional module 1 therefore preserves its desirable ability (e.g., optical ability) and its desirable shape. The distance between the micromirror chip 10 and the electrode substrate 30 can be adjusted by changing the thickness of the joining members 20. This helps the three-dimensional module 1 to preserve the desirable ability and shape.

Thus, this embodiment can achieve the same advantages as the first embodiment described above. In this embodiment, the stress-absorption members 72 are interconnect members such as Au interconnects, and the middle part 72b of each stress-absorption member 72 is curved in the direction of thickness of the three-dimensional module 1. The level at which the electrically conductive stress-absorption members 71 lie can therefore be low, reducing the gap between the electrode substrate 30 and drive substrate 40. That is, the three-dimensional module 1 acceding to this embodiment can be thin.

In the present embodiment, the projections 74a and 74b adjust the height of the middle parts 72b. Nonetheless, the projections 74a or the projections 74b need not be provided if the middle parts 72b do not contact the drive substrate 40 but contact the projections 33a and can yet adjust the height of the middle parts 72b.

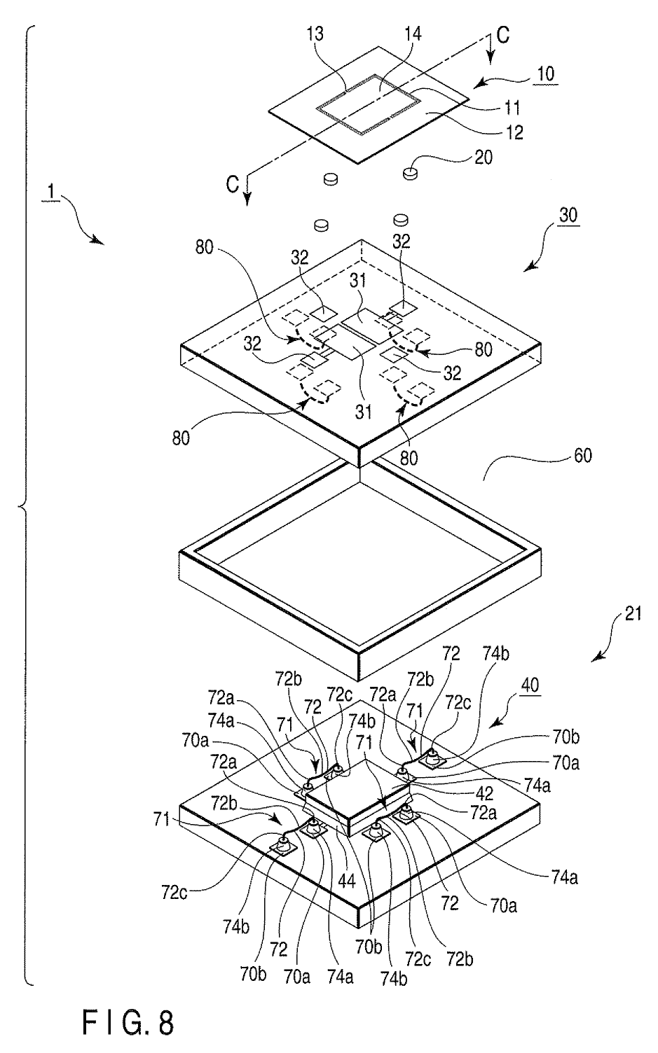

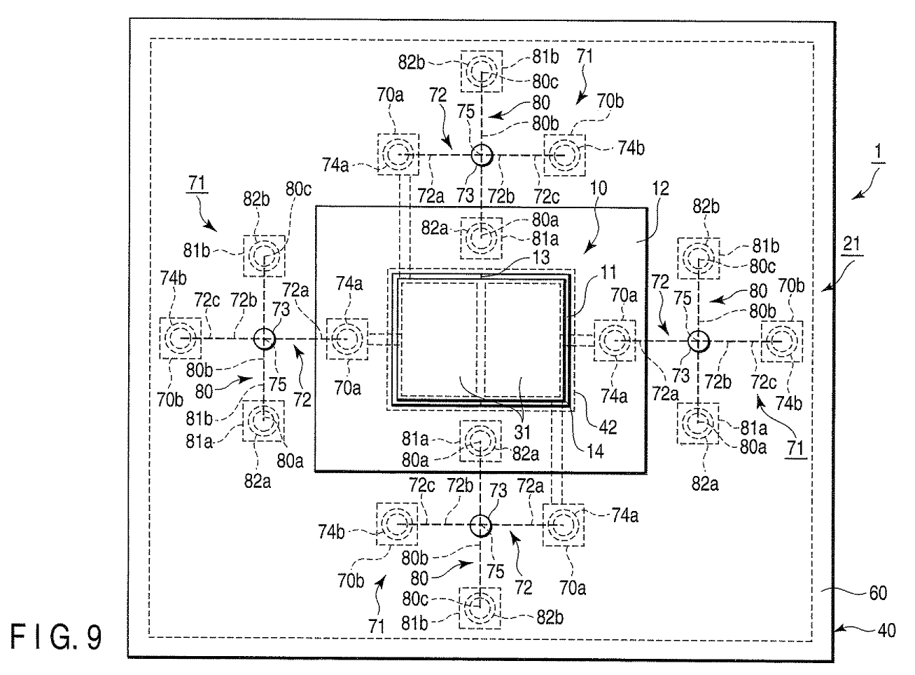

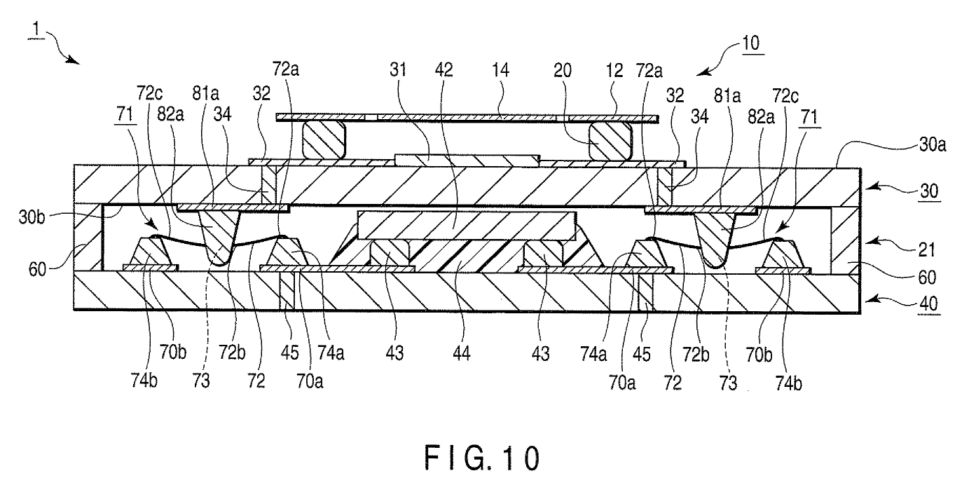

A variation of the second embodiment of the present invention will be described with reference to FIGS. 8 to 10. In FIG. 9, some components, such as joining members 20 and joining electrodes 32, are not illustrated.

In the second embodiment, each electrically conductive stress-absorption member 71 has a stress-absorption member 72, a projection 33a and an electrically conductive fixing part 73. The invention is not limited to this configuration.

In this variation of the second embodiment, each electrically conductive stress-absorption member 71 has a stress-absorption member 72, an electrically conductive fixing part 73, and a stress-absorption member 80. The stress-absorption member 80 is similar in shape to the stress-absorption member 72, opposes the stress-absorption member 72 and intersects with the stress-absorption member 72.

As shown in FIG. 9, four sets of back joining electrodes, each set consisting of two back joining electrodes 81a and 81b, are arranged around the drive electrodes 31. The back joining electrode 81a and 81b are arranged on the back 30b

The back joining electrode 81a of each set is electrically connected to a joining electrode 32 by a through-electrode 34. Each back joining electrode 81b has a projection 82b.

The stress-absorption member 80 has a distal end 80a metal-joined to the back joining electrode 81a by means of ultrasonic vibration. A desirable past as a part of the stress-absorption member 80 (e.g., middle part 80b) is curved. The proximal end 80c of stress-absorption member 80 is metal-joined to, for example, the back joining electrode 81b by means of ultrasonic vibration. The stress-absorption members 80 are interconnect members such as Au interconnects.

More precisely, the distal ends 80a are metal-joined to the back joining electrodes 81a by means of ultrasonic vibration, forming projections 82a. The proximal end 80c of each stress-absorption member 80 is metal-joined to the associated projection 82b by means of ultrasonic vibration. The middle part 80b of each stress-absorption member 80 is curved in the direction of thickness of the third-dimensional module 1, forming a curved part, and does not contact the electrode substrate 30 or the drive substrate 40. The middle part 80b has its height adjusted by the projections 82a and 82b. Since the middle part 80b is curved, the stress-absorption member 80 can deform in a desirable direction. When stress develops in the drive substrate 40, the middle part 80b is bent, deforming in the desired direction. The stress-absorption member 80 therefore absorbs the stress. Further, the stress-absorption member 80 lies at a level lower than the electrically conductive stress-absorption members 46 of the first embodiment.

The stress-absorption members 80 intersect with the stress-absorption member 71, the middle part 80b of each member 80 abuts on the middle part 72b of the associated member 72. In intersection point which the middle part 80b intersect with the middle part 72b, each electrically conductive fixing part 73 electrically connects a stress-absorption member 72 to the associated stress-absorption members 80. The electrically conductive fixing parts 73 are made of electrically conductive adhesive or the like.

Thus, this variation of the second embodiment can achieve the same advantages as the second embodiment described above. In this variation of the second embodiment, the electrode substrate 30 and drive substrate 40 can be easily connected, because the stress-absorption members 80 intersect with the electrically conductive stress-absorption member 71.

The present invention is not limited to the embodiments described above. The components of any embodiment can be modified in various manners in reducing the invention to practice, without departing from the sprit or scope of the invention. Further, the components of any embodiment described above may be combined, if necessary, in various ways to make different inventions.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A three-dimensional module having a first substrate holding a function element, a second substrate holding other components, laid on the first substrate in a three-dimensional fashion and jointed to the first substrate electrically and mechanically, the module comprising:
inter-substrate joining members interposed between the first substrate and the second substrate, joining the first substrate and the second substrate, and each having:
a stress-absorption joining member having elasticity and mechanically joining the first substrate and the second substrate; and
an electrically conductive stress-absorption member electrically joining the first substrate and the second substrate and able to deform in a desirable direction.

2. The three-dimensional module according to claim 1, wherein the electrically conductive stress-absorption member has a stress-absorption part and an electrically conductive fixing part, the stress-absorption part having a distal end metal-jointed to an electrode arranged on the second substrate, a desirable part being curved, and a proximal end metal-joined to the desirable part and thus shaped like a ring, the desirable part being able to bend when stress is generated in the second substrate, whereby the electrically conductive stress-absorption member deforms in a desirable direction to absorb the stress, and the electrically conductive fixing part electrically connecting that part of the stress-absorption part, which is close to the first substrate, to the electrode arranged on the second substrate.

3. The three-dimensional module according to claim 2, wherein the stress-absorption part is an interconnect member made of Au.

4. The three-dimensional module according to claim 2, wherein the electrically conductive fixing part is made of electrically conductive adhesive.

5. The three-dimensional module according to claim 2, wherein the stress-absorption joining member is a rectangular elastic member having a size almost equal to or smaller than sizes of the first and second substrates.

6. The three-dimensional module according to claim 2, wherein the stress-absorption joining member has a height almost equal to a height of the electrically conductive stress-absorption member.

7. The three-dimensional module according to claim 1, wherein the electrically conductive stress-absorption member has a stress-absorption part, a member provided on an electrode arranged on the first substrate and opposing a desirable part, and an electrically conductive fixing part electrically connecting the stress-absorption part and the member,
the stress-absorption part having a distal end metal-joined to one of two electrodes arranged on the second substrate, having a desirable part curved, and a proximal end metal-joined to the other of the two electrodes, the desirable part being able to bend when stress is generated in the second substrate, whereby the electrically conductive stress-absorption member deforms in a desirable direction to absorb the stress.

8. The three-dimensional module according to claim 7, wherein the stress-absorption part is an interconnect member made of Au.

9. The three-dimensional module according to claim 7, wherein the electrically conductive fixing part is made of electrically conductive adhesive.

10. The three-dimensional module according to claim 7, wherein the stress-absorption joining member is a rectangular elastic member having a size almost equal to or smaller than sizes of the first and second substrates.

11. The three-dimensional module according to claim 7, wherein the stress-absorption joining member has a height almost equal to a height of the electrically conductive stress-absorption member.

12. The three-dimensional module according to claim 1, wherein the electrically conductive stress-absorption member has a first stress-absorption part, a second stress-absorption part, and an electrically conductive fixing part,
the first stress-absorption part having a distal end metal-joined to one of two electrodes arranged on the first substrate, having a desirable part curved, and a proximal end metal-joined to the other of the two electrodes, the desirable part being able to bend when stress is generated in the second substrate, whereby the electrically conductive stress-absorption member deforms in a desirable direction to absorb the stress,
the second stress-absorption part opposing the first stress-absorption part, intersecting with the first stress-absorption part, having a distal end metal-joined to one of two electrodes arranged on the second substrate, having a desirable part curved, and a proximal end metal-joined to the other of the two electrodes, the desirable part being able to bend when stress is generated in the second substrate, whereby the electrically conductive stress-absorption member deforms in a desirable direction to absorb the stress, and
the electrically conductive fixing part electrically connecting the stress-absorption part and the member at an intersection point of the first stress-absorption part and second stress-absorption part.

13. The three-dimensional module according to claim 12, wherein the stress-absorption part is an interconnect member made of Au.

14. The three-dimensional module according to claim 12, wherein the electrically conductive fixing part is made of electrically conductive adhesive.

15. The three-dimensional module according to claim 12, wherein the stress-absorption joining member is a rectangular elastic member having a size almost equal to or smaller than sizes of the first and second substrates.

16. The three-dimensional module according to claim 12, wherein the stress-absorption joining member has a height almost equal to a height of the electrically conductive stress-absorption member.
